(19) United States
(12) Patent Application Publication
(10) Pub. No.: US 2026/0362773 A1
(43) Pub. Date: Nov. 12, 2026

(54) SEMICONDUCTOR DEVICE AND METHOD FOR PROVIDING ELECTRODE IN SEMICONDUCTOR DEVICE

(71) Applicants: NEXPERIA TECHNOLOGY (SHANGHAI) LTD., Shanghai (CN); NEXPERIA B.V., Nijmegen (NL)

(72) Inventors: Jianglong YIN, Shanghai (CN); Xiaorong CHEN, Shanghai (CN); Fan CHEN, Shanghai (CN); Yanming CHEN, Shanghai (CN)

(73) Assignees: NEXPERIA TECHNOLOGY (SHANGHAI) LTD., Shanghai (CN); NEXPERIA B.V., Nijmegen (NL)

(21) Appl. No.: 19/723,400

(22) Filed: Jun. 29, 2026

Related U.S. Application Data
(63) Continuation of application No. PCT/CN2023/142216, filed on Dec. 27, 2023.

(51) Int. Cl. H10D 64/01; H10D 12/00; H10D 12/01; H10D 30/01; H10D 30/66; H10D 64/00

(52) U.S. Cl. CPC H10D 64/027; H10D 12/038; H10D 12/481; H10D 30/0297; H10D 30/668; H10D 64/117

(57) ABSTRACT

A method for providing an electrode in a semiconductor device is provided. The method includes obtaining a semiconductor device having a semiconductor body. The semiconductor body includes a first surface and a cavity extending from the first surface. The cavity includes a corner defined by a sidewall and a base wall. The method further includes forming a material layer in the cavity overlying the corner, isotropically etching the material layer so that the etched material formed over the corner rounds the corner, and forming an electrode in the cavity with the rounded corner.

### CROSS-REFERENCE TO RELATED APPLICATIONS

This application is a continuation of PCT/CN2023/142216 filed on Dec. 27, 2023, the contents of which are incorporated by reference herein in its entirety.

### BACKGROUND

### 1. Field of the Disclosure

Embodiments described herein relate to a semiconductor device and a method for providing an electrode in a semiconductor device.

### 2. Description of the Related Art

Semiconductor devices such as trench-gate based metal oxide semiconductor field effect transistors (MOSFET) are known. One problem associated with some of these existing semiconductor devices is that the gate electrode of the device may have sharp bottom corners. These sharp bottom corners can cause undesirable corner effect, which results in relatively high gate current leakage and/or relatively high electric field, hence may degrade the performance of the semiconductor device.

### SUMMARY

Embodiments described herein attempt to address or at least to ameliorate at least one of the above undesirable effects, by providing a method for providing an electrode in a semiconductor device. The method can be used to fabricate the semiconductor device. The method in some embodiments of the invention can help reduce sharpness of one or more of the bottom corners of the gate electrode in relatively simple and effective way. The method in some embodiments of the disclosure can be implemented relatively easily, relatively quickly, and/or relatively cost-effectively for fabricating semiconductor device such as trench-gate based semiconductor device. The method in some embodiments of the disclosure can be readily incorporated into existing semiconductor device fabrication procedures. The semiconductor device made based on the method in some embodiments of the disclosure can have improved performance such as improved figure of merit (FOM).

In a first aspect, there is provided a method for providing an electrode in a semiconductor device. The method includes obtaining a semiconductor device having a semiconductor body with a first surface and a cavity extending from the first surface. The cavity includes a corner defined by a sidewall and a base wall. The method further includes forming a material layer in the cavity overlying the corner, isotropically etching the material layer so that the etched material formed over the corner rounds the corner, and forming an electrode in the cavity with the rounded corner. By forming and then isotropically etching the material layer, the corner of the cavity can be rounded relatively easily. The cavity with the rounded corner can in turn facilitate formation of an electrode a rounded corner, thus reducing the undesirable corner effect.

In some embodiments, the cavity includes more than one corner. In these embodiments, the material layer formed in the cavity overlies multiple corners of the cavity and the isotropically etching of the material layer results in etched material formed over all of these corners to round these corners. In some examples, the multiple rounded corners are formed simultaneously. The cavity with the multiple rounded corners can facilitate formation of an electrode with multiple rounded corners. A larger number of rounded corners can better reduce the undesirable corner effect. Simultaneously formation of multiple rounded corners can improve efficiency of the method.

In some embodiments, the material layer includes a dielectric layer, and the etched material formed over the corner includes etched dielectric. In some embodiments, the dielectric layer includes an oxide layer. In some embodiments, the oxide layer consists essentially of silicon dioxide.

In some embodiments, forming the material layer includes forming the material layer on all walls of the cavity (i.e., at least the sidewall and the base wall) so that the material layer covers all of the walls of the cavity.

In some embodiments, forming the material layer includes depositing the material layer. In some embodiments, depositing the material layer includes isotropically depositing the material layer.

In some embodiments, the isotropic etching of the material layer removes most of the material layer, leaving etched material only at the corner of the cavity (if the cavity includes only one corner) or only at all corners of the cavity (if the cavity includes multiple corners). As a result, the remaining parts of the walls of the cavity (i.e., except at the corner or the corners) can be kept relatively clean after the etching. In some cases, the thickness of the walls of the cavity can thus remain substantially the same as it was before the forming of the material layer. This may facilitate control of the thickness of the walls of the cavity.

In some embodiments, the sidewall and the base wall are dielectric walls. The dielectric walls are made of dielectric material. In some embodiments, the dielectric material includes oxide. In some embodiments, the oxide consists essentially of silicon dioxide.

In some embodiments, the thickness of the material layer formed is substantially constant.

In some embodiments, the thickness of the material layer formed is at least 0.05 microns. In some embodiments, the thickness of the material layer formed is at least 0.1 microns.

In some embodiments, the thickness of the material layer formed is between about 0.2 microns to about 0.5 microns. In some embodiments, the thickness of the material layer formed is between about 0.25 microns to about 0.45 microns. In some embodiments, the thickness of the material layer formed is between about 0.3 microns to about 0.4 microns. In some embodiments, the thickness of the material layer formed is about 0.3 microns. In some embodiments, the thickness of the material layer formed is about 0.4 microns. In some cases, these thicknesses or thickness ranges of the material layer can provide improved corner rounding result and/or can lead to improved figure of merit of the semiconductor device.

In some embodiments, the electrode includes a gate electrode. In some embodiments, the gate electrode is made of a conductive material such as polysilicon.

In some embodiments, obtaining the semiconductor device includes: obtaining a body including a trench with a first trench portion and a second trench portion, the first trench portion receives a dielectric arrangement with another electrode embedded in the dielectric arrangement.

In some embodiments, obtaining the semiconductor device further includes: forming a dielectric layer on a sidewall of the second trench portion of the trench so that the formed dielectric layer provides the sidewall of the cavity.

In some embodiments, the dielectric arrangement provides the base wall of the cavity.

In some embodiments, the dielectric arrangement includes an oxide arrangement. In some embodiments, the oxide arrangement consists essentially of silicon dioxide.

In some embodiments, the dielectric arrangement and the another electrode fill the first trench portion.

In some embodiments, the another electrode and the electrode are generally aligned along a depth of the trench. The another electrode and the electrode may have different shapes and/or sizes.

In some embodiments, the another electrode includes a shield electrode. In some embodiments, the shield electrode is made of a conductive material such as polysilicon.

In some embodiments, the trench consists only of the first trench portion and the second trench portion. In some embodiments, the first trench portion is arranged below the second trench portion. In some embodiments, the length of the first trench portion is longer than the length of the second trench portion, as measured along the depth of the trench.

The body is made of semiconductor material. For example, body can be a silicon body, a silicon carbon (SiC) body, or a gallium nitride (GaN) body.

In some embodiments, the body includes a silicon body which provides the sidewall of the second trench portion. In some embodiments, forming the dielectric layer on the sidewall includes thermally oxidizing the sidewall (provided by the silicon body) or the silicon body. In some embodiments, the silicon body includes one or more epitaxial layers.

In some embodiments, the method further includes: forming a dielectric layer on a sidewall of the cavity with the rounded corner, and forming the electrode in the cavity with the rounded corner and the dielectric sidewall. In some of these embodiments in which the body includes a silicon body which provides the sidewall of the second trench portion, forming the dielectric layer on the sidewall of the cavity with the rounded corner includes thermally oxidizing the sidewall (provided by the silicon body) or the silicon body. In some embodiments, the silicon body includes one or more epitaxial layers.

In some embodiments, the semiconductor device is a trench-gate based semiconductor device. In some embodiments, the trench-gate based semiconductor device is a trench-gate based metal oxide semiconductor field effect transistor (MOSFET). In some embodiments, the trench-gate based semiconductor device is a trench-gate based insulated gate bipolar transistor (IGBT).

In some embodiments, the trench-gate based semiconductor device is a shielded gate trench (SGT) semiconductor device. In some embodiments, the SGT semiconductor device is a SGT MOSFET. In some embodiments, the SGT semiconductor device is a SGT IGBT.

In a second aspect, there is provided a semiconductor device fabricated using the method of the first aspect. In some examples, the semiconductor device is a trench-gate based semiconductor device, such as a trench-gate based metal oxide semiconductor field effect transistor (MOSFET) or a trench-gate based insulated gate bipolar transistor (IGBT). In some examples, the trench-gate based semiconductor device is a shielded gate trench (SGT) semiconductor device, such as a SGT MOSFET or a SGT IGBT.

In a third aspect, there is provided an electronic device that includes the semiconductor device of the second aspect.

Other features and aspects of the disclosure will become apparent by consideration of the detailed description and accompanying drawings. Any feature(s) described herein in relation to one aspect or embodiment can be combined with any other feature(s) described herein in relation to any other aspect or embodiment as appropriate and applicable.

As used herein, “conductive” means at least electrically conductive. As used herein, terms of degree such as “generally”, “about”, “substantially”, or the like, are used, depending on context, to account for one or more of the following: manufacture tolerance, degradation, trend, tendency, imperfect practical condition(s), etc. As used herein, when a value is modified by terms of degree, such as “about”, such expression may include the stated value ±20%.

### BRIEF DESCRIPTION OF THE DRAWINGS

Embodiments of the disclosure will now be described, by way of example, with reference to the accompanying drawings in which:

FIG. 1 is a schematic diagram illustrating a method for providing an electrode in a semiconductor device in some embodiments.

FIG. 2A is a schematic diagram illustrating a method for fabricating a shielded gate trench (SGT) MOSFET in some embodiments.

FIG. 2B is a schematic diagram illustrating the SGT MOSFET fabricated using the method of FIG. 2A.

FIGS. 3A, 3B, 3C, 3D, 3E, 3F, 3G, 3H, 3I, 3J, 3K, 3L, 3M, 3N, 3O, 3P, 3Q, 3R, 3S, 3T, 3U, 3V and 3W are schematic diagrams illustrating a method for fabricating a shielded gate trench (SGT) MOSFET in some embodiments.

FIG. 4A is a graph showing the relationship between the Q_{gd}*Rₛₚ (gate-drain charge times on-state specific resistance) figure of merit (FOM) value and the thickness of the initially deposited oxide in the method of FIG. 2A in one example simulation.

FIG. 4B is a graph showing the relationship between the Q_{g}*Rₛₚ (gate charge times on-state specific resistance) figure of merit (FOM) value and the thickness of the initially deposited oxide in the method of FIG. 2A in one example simulation.

FIG. 5 are schematic diagrams showing the profiles of the corner obtained from different thicknesses of the initially deposited (and subsequently etched) oxide in one example simulation.

FIG. 6 is a schematic diagram illustrating a SGT MOSFET fabricated using a method that is not part of the disclosure.

FIG. 7 is a scanning electron microscopy (SEM) image of a SGT MOSFET fabricated using a method that is not part of the disclosure.

### DETAILED DESCRIPTION

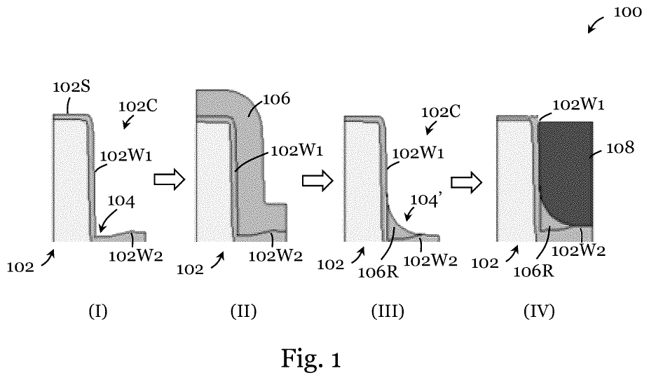

FIG. 1 shows a method 100 for providing an electrode in a semiconductor device in accordance with an embodiment. In FIG. 1, only the most relevant parts of the semiconductor device are shown (not drawn to scale) and the parts are shown in cross-sectional-half, to facilitate understanding of these embodiments of the disclosure. In some examples, the other cross-sectional-half is generally the same as the cross-sectional-half shown (and the two halves are generally symmetrically disposed). In some examples, the other cross-sectional-half may be different from the cross-sectional-half shown.

The method 100 includes, in stage (I), obtaining a semiconductor device with a semiconductor body 102. The semiconductor body 102 includes a first surface 102S and a cavity 102C extending from the first surface 102S. In this example, the first surface 102S is a top surface. The cavity 102C includes a corner 104 defined by a sidewall 102W1 and a base wall 102W2 of the semiconductor body 102. In this example, the corner 104 is a generally L-shaped corner in cross-sectional view.

The method 100 further includes, in stage (II), forming a material layer 106 in the cavity 102C overlying the corner 104. In one example, the material layer is a dielectric layer. In this example, the material layer 106 is formed on and hence covers the first surface 102S, the sidewall 102W1, and the base wall 102W2. In one example, the material layer covers all walls of the cavity (the sidewall 102W1 and the base wall 102W2 and the other wall(s) in the other cross-sectional-half) and does not fill the entire space defined by the sidewall 102W1 and the base wall 102W2. In this example, the dielectric layer has a substantially constant thickness, which may be in the order of micron or sub-micron. In one example, the material layer is formed by deposition, which may be isotropic.

The method 100 then includes, in stage (III), isotropically etching the material layer 106. As a result of the isotropic etching, the material layer 106 is removed at substantially the same rate in all directions and etched material 106R is formed over the corner 104 to round the corner 104. In this example, most of the material layer 106 on the first surface 102S, the sidewall 102W1, and the base wall 102W2 have been removed by the etching. If the cavity includes another corner in the other cross-sectional-half, then etched material could also be formed over that corner. In embodiments in which the material layer 106 is a dielectric layer, the etched material 106R is etched dielectric.

Finally, the method 100 includes, in stage (IV), forming an electrode 108 in the cavity 102C with the rounded corner 104′. The electrode 108 formed thus also includes a rounded corner at the rounded corner 104′. In some examples, the electrode 108 is a gate electrode. In one example, the electrode 108 is formed by deposition of a conductive material such as polysilicon.

The method 100 can be applied to provide electrode in different types of semiconductor devices. For example, the method 100 can be applied to provide an electrode in a trench-gate based semiconductor device. It should be appreciated that in some embodiments method 100 may include one or more further or different stages not illustrated in FIG. 1.

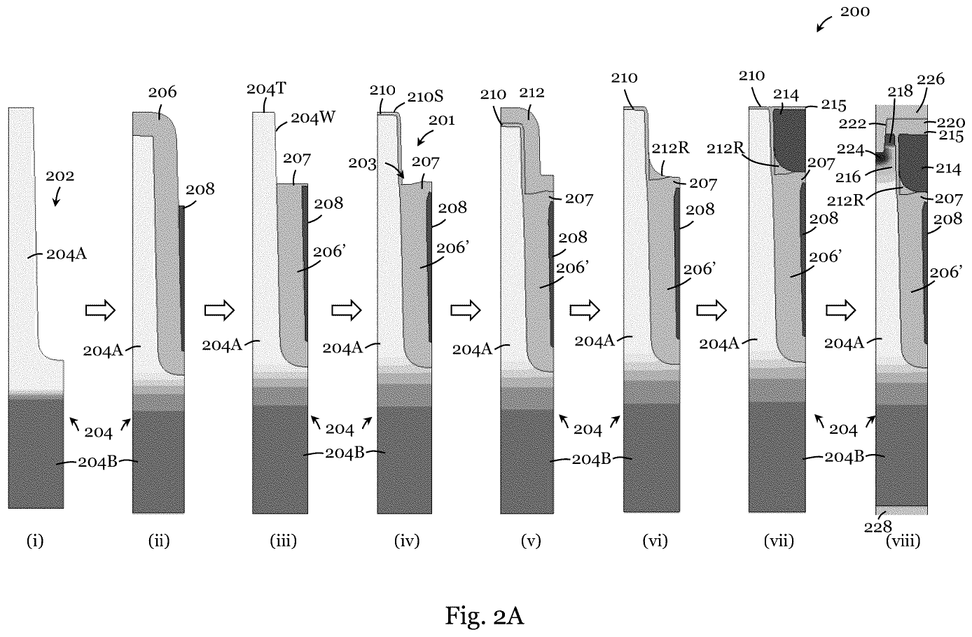

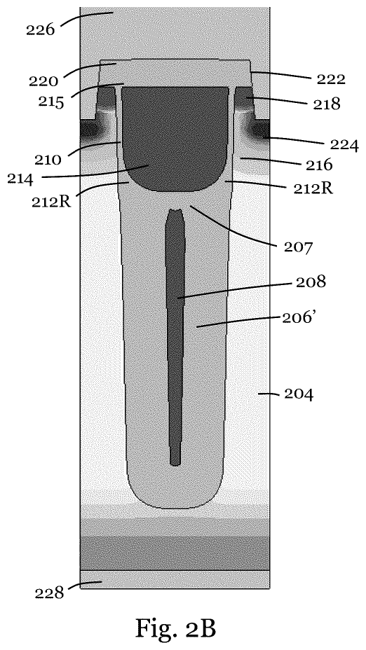

FIG. 2A shows an operation 200 for fabricating a trench-gate based semiconductor device in the form of a shielded gate trench (SGT) MOSFET in some embodiments. In FIG. 2A, only cross-sectional-half (not drawn to scale) is shown and only the main steps are illustrated, to facilitate understanding of these embodiments of the disclosure. It should be appreciated that in some embodiments operation 200 may include one or more further or different stages not illustrated in FIG. 2A.

Stages (i) to (iv) in FIG. 2A demonstrate an example to arrive at stage (I) in FIG. 1. Specifically, in stage (i), a semiconductor body 204 (formed by an epitaxial silicon layer 204A and a substrate 204B supporting the epitaxial silicon layer 204A) is etched from its top surface to form an elongated trench 202. In stage (ii), a liner dielectric 206 is deposited on the top surface of the semiconductor body 204 and on the walls of the semiconductor body 204 defining the trench 202. In this example, the liner dielectric 206 is a liner oxide formed by silicon dioxide. In some other examples, the liner dielectric 206 may be formed by other dielectric material such as multi-layer dielectric. For example, the multi-layer dielectric can be a bi-layer dielectric (e.g., silicon dioxide (SiO₂) layer+ silicon nitride (Si₃N₄) layer) or tri-layer dielectric (e.g., silicon dioxide (SiO₂) layer+ silicon nitride (Si₃N₄) layer+ silicon dioxide (SiO₂) layer). In one example, the deposition of the liner dielectric 206 is performed using chemical vapor deposition (CVD) technique such as sub-atmospheric chemical vapor deposition (SACVD) technique. Further, a polysilicon (poly) material is deposited at least in a space defined by the liner dielectric 206 and is subsequently etched back, thus forming a polysilicon (poly) body 208, which can operate as a shield electrode. In one example, the deposition of the polysilicon (poly) material is performed using furnace tube. In one example, the subsequent etch back of the polysilicon (poly) material is performed using dry etch back technique. In stage (iii), the liner dielectric 206 is etched back, e.g., isotropically, such that most or all of the oxide disposed between the polysilicon body 208 and the walls of the trench 202 remains, and optionally exposing a top portion of the polysilicon body 208. The oxide disposed between the polysilicon body 208 and the walls of the trench 202 can operate as shield oxide 206′. Then, an oxide (silicon dioxide) is deposited over the shield oxide and over the top portion of the polysilicon body 208 (if it is exposed). In one example, the deposition of the oxide is performed using high density plasma deposition. The deposited oxide is then subjected to chemical-mechanical polishing and is etched back, thereby providing an oxide layer 207 covering the polysilicon body 208 and the shield oxide 206′. In one example, the etch back is performed using dry etch back technique. The oxide layer 207 may operate as an inter-electrode dielectric. An oxide layer 210 (silicon dioxide) is then thermally grown or otherwise formed on the top surface 204T of the semiconductor body 204 (the epitaxial silicon layer 204A) and on the exposed (not covered by oxide) part of the sidewall 204W of the semiconductor body 204 (the epitaxial silicon layer 204A) defining the trench 202. The thermal growing process converts the silicon into oxide (silicon dioxide). The thermal oxide grown on the sidewall 204W may operate as gate oxide. As shown in stage (iv), the resultant semiconductor body 204 includes a top surface 210S and a cavity 201 extending from the top surface 210S, and the cavity 201 includes a corner 203 defined by a sidewall and a base wall.

Stage (v) in FIG. 2A demonstrates an example to arrive at stage (II) in FIG. 1. Specifically, in stage (v), an oxide layer 212 (silicon dioxide) is isotropically deposited on the top surface 210S and the sidewall and base wall of the cavity 201. The oxide layer 212 thus overlies the corner 203 without filling the entire cavity 201. The isotropic deposition of the oxide layer 212 can be performed using technique such as thermal chemical vapor deposition from tetraethylorthosilicate (TEOS) or high density plasma deposition. In one example, the deposition is performed using sub-atmospheric chemical vapor deposition (SACVD) technique.

Stage (vi) in FIG. 2A demonstrates an example to arrive at stage (III) in FIG. 1. Specifically, in stage (vi), the oxide layer 212 is isotropically etched so that the etched oxide 212R is formed over the corner 203. The etched oxide 212R thus rounds the corner 203. Other parts of the oxide layer 212 on the top surface 210S and the sidewall and base wall of the cavity 201 (i.e., all parts of the oxide layer 212 not at the corner 203 and any other corner of the cavity 201) are removed by the isotropic etching.

Stage (vii) in FIG. 2A demonstrates an example to arrive at stage (IV) in FIG. 1. Specifically, in stage (vii), a polysilicon (poly) material is deposited at least in the cavity 201 with the rounded corner and is subsequently etched back, thus forming another polysilicon body 214 which can operate as a gate electrode. In one example, the deposition of the polysilicon (poly) material is performed using furnace tube. In one example, the subsequent etch back of the polysilicon (poly) material is performed using dry etch back technique. This forms an electrode (gate electrode) in the cavity 201 with the rounded corner. In this example, the polysilicon body 214, i.e., the gate electrode, aligns with the polysilicon body 208, i.e., the shield electrode, along a depth of the trench 202. A thin cap oxide layer 215 (silicon dioxide) is further formed on the polysilicon body 214. The thin cap oxide layer 215 may be thermally grown on the polysilicon body 214.

Stage (viii) in FIG. 2A includes further operations for forming the SGT MOSFET. First, a P-body region 216 is formed (e.g., implanted) in the upper section of the semiconductor body 204. In one example, the formation of the P-body region 216 is based on boron implantation. Then a source N-plus region 218 is formed (e.g., implanted) in the upper part of the P-body region 216. In one example, the formation of the source N-plus region is based on arsenic or phosphorus implantation. Further, a dielectric layer 220 is deposited on the exposed part of the gate oxide layer 210 and the cap oxide layer 215. In one example, the dielectric layer 220 is borophosphosilicate glass (BPSG) layer. The dielectric layer 220 can operate as an interlayer dielectric. The dielectric layer 220, the source N-plus region 218, and the P-body region 216 are then etched back from the top surface of the semiconductor body 204 to form a contact region 222 for connecting with a conductive element. A P-plus region 224 is formed (e.g., implanted) in part of the P-body region 216, at the bottom end of the contact region 222. In one example, the formation of the-plus region 224 is based on boron fluoride (BF₂) implantation. A top metal layer 226, operable as a source electrode, is then deposited or otherwise formed at the top end of the semiconductor body 204, in the contact region 222 and on the dielectric layer 220. In one example, the top metal layer 226 is deposited using physical vapor deposition (PVD) technique. A bottom metal layer 228, operable as a drain electrode, is deposited or otherwise formed at the bottom end of the semiconductor body 204. In one example, the bottom metal layer 228 is deposited using physical vapor deposition (PVD) technique. In one example, the substrate 204B (not shown in its entire thickness) at the bottom end of the epitaxial silicon layer 204A for supporting the epitaxial silicon layer 204A is at least partly removed by grinding before the bottom metal layer 228 is deposited or otherwise formed.

FIG. 2B shows a cross sectional view of the SGT MOSFET fabricated based on the operation 200. This view in FIG. 2B generally corresponds to stage (viii) in FIG. 2A. It can be seen that due to the deposition and isotropic etching of the oxide layer 212 in stages (v) and (vi) in FIG. 2A, the cavity that receives the polysilicon body 214 (gate electrode) of the SGT MOSFET has generally rounded bottom corners, and the polysilicon body 214 (gate electrode) of the SGT MOSFET also has generally rounded bottom corners.

The operation 200 in FIG. 2A can be modified to provide some other embodiments of the invention. For example, in some embodiments, stages (v) and (vi) in operation 200 can be performed before stage (iv). In these embodiments, after stage (iii), oxide layer 212 (silicon dioxide) can be isotropically deposited on the top surface 204T of the semiconductor body 204, the exposed (not covered by oxide) part of the sidewall 204W of the semiconductor body 204 defining the trench 202, and the oxide layer 207. The oxide layer 212 thus overlies the corner defined by the sidewall 204W and the oxide layer 207. The oxide layer 212 is then isotropically etched so that the etched oxide is formed over the corner defined by the sidewall 204W and the oxide layer 207, to round the corner. Other parts of the oxide layer 212 (i.e., all parts of the oxide layer 212 not at the corner and any other corner of the cavity) may be removed by the isotropic etching. Then, oxide layer 210 (silicon dioxide) is thermally grown or otherwise formed on the top surface 204T of the semiconductor body 204 and on the exposed (not covered by oxide) part of the sidewall 204W of the semiconductor body 204. The thermal growing process converts the silicon into oxide (silicon dioxide). The thermal oxide grown on the sidewall 204W can operate as gate oxide. After these operations, the operation can then proceed to stage (vii), to deposit the polysilicon (poly) material in the cavity with the rounded corner and the gate oxide sidewall.

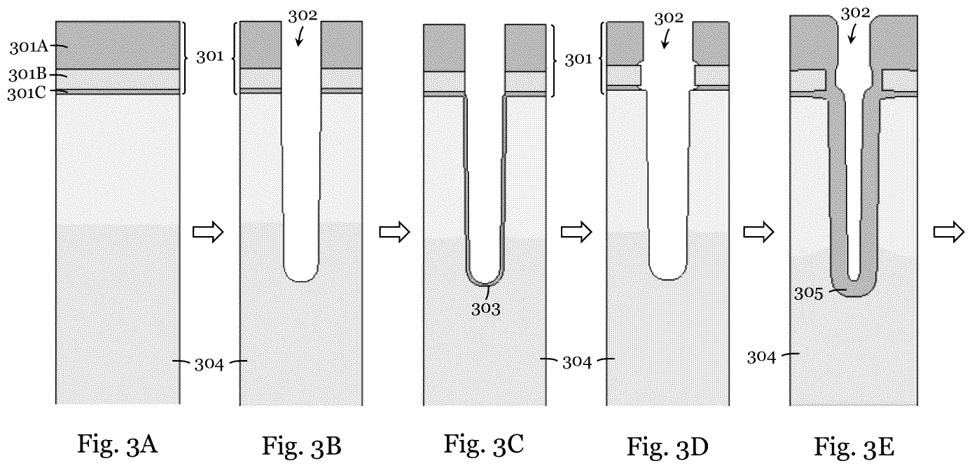

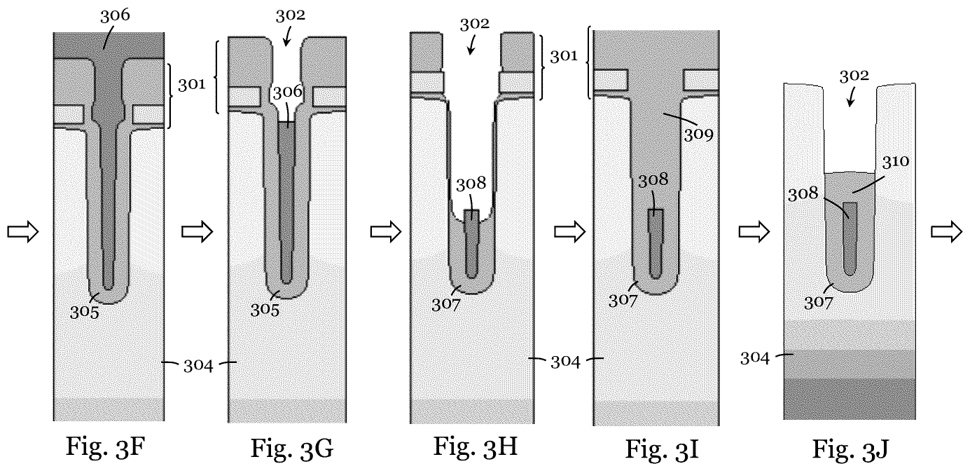

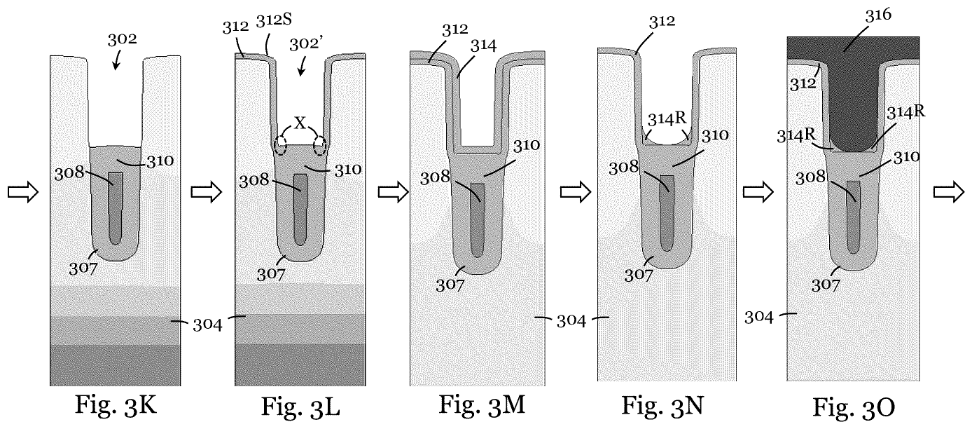

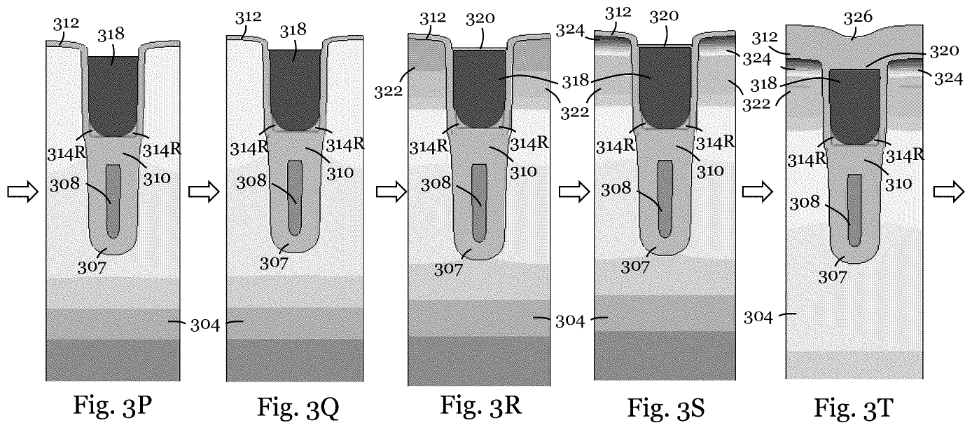

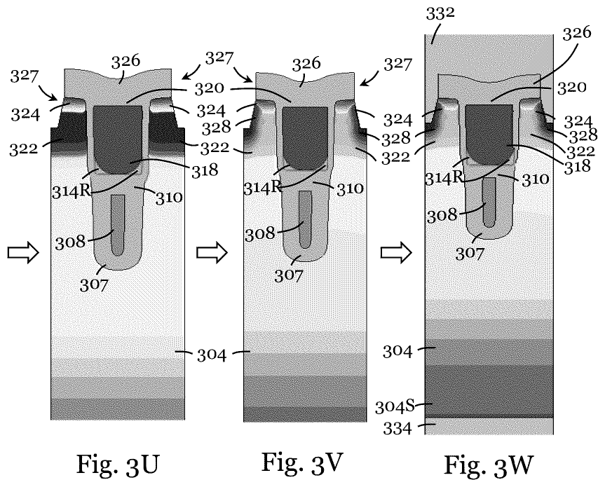

FIGS. 3A to 3W illustrate an operation for fabricating a trench-gate based semiconductor device in the form of a shielded gate trench (SGT) MOSFET in some embodiments. In FIGS. 3A to 3W, only the cross sectional view (not drawn to scale) is shown, to facilitate understanding of these embodiments of the disclosure. FIGS. 3A to 3W can be considered as a more detailed example implementation of the operation 200 in FIG. 2A.

The operation begins from FIG. 3A, in which a mask (hardmask) 301 is deposited on a semiconductor body provided by an epitaxial silicon layer 304, which may be supported by a substrate (not shown). In this example, the mask 301 includes a relatively thick upper oxide layer 301A, a middle silicon nitride (Si₃N₄) layer 301B, and a relatively thin lower oxide layer 301C. In this example, the oxide layers 301A, 301C consist essentially of silicon dioxide (SiO₂). The relatively thin bottom oxide layer 301C is arranged or sandwiched between the middle silicon nitride (Si₃N₄) layer 301B and the epitaxial silicon layer 304.

With the assembly in FIG. 3A, a trench 302 is formed by etching through the mask 301 and the epitaxial silicon layer 304. As shown in FIG. 3B, the trench 302 slightly narrows along its depth and has a generally rounded bottom end.

After the trench 302 is formed in the epitaxial silicon layer 304, a sacrificial oxide layer 303 is then formed on the sidewall and the base wall of the trench 302 portion provided by the epitaxial silicon layer 304, as shown in FIG. 3C. The sacrificial oxide layer 303 lines the inner wall of the trench 302 portion provided by the epitaxial silicon layer 304.

Subsequently, as shown in FIG. 3D, the sacrificial oxide layer 303 is removed to reduce defects on the sidewall and base wall of the trench, and a silicon nitride (Si₃N₄) pull-back process is performed on the mask 301. The Si₃N₄ pull-back process removes part of the middle silicon nitride (Si₃N₄) layer 301B as well as part of the oxide layers 301A, 301C that act as the sidewall of the trench 302 portion provided by the mask 301.

Then, a sacrificial oxide layer is formed or grown, e.g., by thermal oxidation of the sidewall and the base wall of the trench 302 provided by the epitaxial silicon layer 304 along the sidewall and the base wall of the trench 302, and is subsequently etched back. A liner dielectric layer 305 is then deposited along the sidewall and the base wall of the trench 302 (both the trench portion provided by the epitaxial silicon layer 304 and the trench portion provided by the mask 301). In this example, the liner dielectric layer 305 is a liner oxide layer formed by silicon dioxide. In some other examples, the liner dielectric layer 305 may be formed by other dielectric material such as multi-layer dielectric. For example, the multi-layer dielectric can be a bi-layer dielectric (e.g., silicon dioxide (SiO₂) layer+ silicon nitride (Si₃N₄) layer) or tri-layer dielectric (e.g., silicon dioxide (SiO₂) layer+ silicon nitride (Si₃N₄) layer+ silicon dioxide (SiO₂) layer). The liner oxide layer can be formed by thermal oxidation as well as chemical vapor deposition (CVD) so the liner oxide layer includes thermal oxide and CVD oxide. The silicon nitride layer can be formed by chemical vapor deposition or plasma enhanced chemical vapor deposition. The liner dielectric layer 305 lines the sidewall and the base wall of the trench 302, defining a small empty space in the trench 302, as shown in FIG. 3E.

With the liner dielectric layer 305 formed, a polysilicon (poly) material 306 is then filled in the space defined by the liner dielectric layer 305 and over the mask 301, as shown in FIG. 3F. In this example, the filling process involves depositing, chemical-mechanical polishing, and annealing the polysilicon material 306.

Then, the polysilicon material 306 is etched back, to remove the parts of the polysilicon material above the mask 301 and in the trench 302 portion defined by the mask 301, as shown in FIG. 3G.

The polysilicon material 306 is then further etched back, to remove the upper parts of the polysilicon material in the trench 302 portion defined by the epitaxial silicon layer 304, to form the shield electrode 308 (provided by the polysilicon material that remains). The liner dielectric layer 305 is also etched to remove its parts formed on the sidewall of the trench 302 portion defined by the mask 301 and to remove most of its parts formed on the sidewall of the trench 302 portion defined by the epitaxial silicon layer 304 at and above the shield electrode 308 such that the upper end of the shield electrode 308 is exposed. The liner dielectric layer 305 that remains after the etching provides a shield oxide 307 for the shield electrode 308, and optionally a thin lining on the sidewall of the trench 302 portion defined by the epitaxial silicon layer 304 above the shield oxide 307. FIG. 3H shows the resultant configuration.

Oxide 309 (silicon dioxide) is then deposited, using high density plasma deposition, to fill the remaining space of the trench 302, as shown in FIG. 3I.

Next, the mask 301 is removed and the oxide 309 is etched back. Specifically, chemical-mechanical polishing is performed on the mask 301 to remove the oxide (the portion of the oxide 309 and the upper oxide layer 301A) above the middle silicon nitride (Si₃N₄) layer 301B of the mask. Then, the middle silicon nitride (Si₃N₄) layer 301B is stripped. The thin lower oxide layer 301C is removed. The oxide 309 is removed from the upper ends of the trench 302, leaving behind an oxide portion covering the shield oxide 307 and the shield electrode 308. The oxide portion that remains provides an inter poly oxide (or inter electrode oxide) 310. FIG. 3J shows the resultant configuration.

Then, a gate oxide pre-cleaning process is performed. Further, a sacrificial oxide layer is formed or grown, e.g., by thermal oxidation of the exposed parts of the sidewall of the trench 302 provided by the epitaxial silicon layer 304, and subsequently etched back. FIG. 3K shows the resultant configuration.

As shown in FIG. 3L, an oxide layer 312 is then grown, e.g., by thermal oxidation of the sidewall of the trench 302 provided by the epitaxial silicon layer 304 and the top surface of the epitaxial silicon layer 304. As shown in FIG. 3L, the oxide layer 312 and the inter poly oxide 310 defines, in the trench 302, a cavity 302′ provided by sidewalls and base wall, with sharp corners X defined the sidewalls and the base wall of the cavity 302′. At least the portion of the oxide layer 312 formed on the sidewall of the trench 302 can operate as a gate oxide.

The operations from FIG. 3A to FIG. 3L demonstrate an example to arrive at stage (I) in FIG. 1. As shown in FIG. 3L, the semiconductor body includes a first surface 312S and a cavity 302′ extending from the first surface 312S, and the cavity 302′ includes corners X defined by sidewalls and base wall.

With the oxide layer 312 formed, a further oxide layer 314 is then deposited on the oxide layer 312, as shown in FIG. 3M. In this example, the further oxide layer 314 is isotropically deposited on the oxide layer 312, hence lines the oxide layer 312 and has a relatively constant thickness (without filing the cavity 302′. The oxide layer 312 and the further oxide layer 314 both consist essentially of silicon dioxide. The operation in FIG. 3M demonstrates an example to arrive at stage (II) in FIG. 1.

The deposited oxide layer 314 is then isotropically etched. As a result of the isotropic etching, most of the deposited oxide layer 314 is removed and only a small amount of oxide residue 314R is left at the corners X to overlie the corners X. The oxide residue 314R helps to round the corners X (or at least, make the corners X less sharp), as shown in FIG. 3N. The operation in FIG. 3N demonstrates an example to arrive at stage (III) in FIG. 1.

With the corner rounding operation completed, a polysilicon (poly) material 316 is deposited inside the cavity 302′ with the rounded corners (defined by the oxide layer 312 and the oxide residue 314R) and over the oxide layer 312. A chemical-mechanical polishing operation is performed on the polysilicon material 316. FIG. 3O shows the resultant configuration.

The polysilicon material 316 is then etched back, to remove its portion outside the trench 302 or cavity 302′, to form a gate electrode 318 inside the trench 302 or cavity 302′, as shown in FIG. 3P.

P-body screen oxide (silicon dioxide) is then partially etched back to prepare for the formation of a P-body region. FIG. 3Q shows the resultant configuration. Then, a P-body region 322 is formed (e.g., implanted) in the upper end region of the epitaxial silicon layer 304 adjacent the oxide layer 312 and a thin cap oxide layer 320 is grown (e.g., by thermal oxidation) on the gate electrode 318, as shown in FIG. 3R. A source N-plus region 324 is formed (e.g., implanted) in the upper part of the P-body region 322, as shown in FIG. 3S. Then, a dielectric layer 326 is deposited over the oxide layer 312 and the thin cap oxide layer 320, as show in FIG. 3T. The dielectric layer 326 is used as an interlayer dielectric.

Subsequently, an etching operation is performed from the top surface of the assembly in FIG. 3T to form contact (hole) regions 327 at the sides of the dielectric layer 326 and the sides of the upper part of the source N-plus region 324 and the P-body region 322. The resultant configuration is shown in FIG. 3U.

A P-plus region 328 is then formed (e.g., implanted) at the upper part of the side of the P-body region 322, as shown in FIG. 3V. In one example, boron fluoride (BF₂) is deposited or otherwise arranged in the contact (hole) regions 327. Finally, an upper (or front) metal layer 332 is deposited over the contact region 327 and the dielectric layer 326. This upper (or front) metal layer 332 is arranged to provide a source electrode. Part of the substrate 304S supporting the epitaxial silicon layer 304 may be removed (e.g., to reduce its thickness) by grinding. A lower (or back) metal layer 334 is deposited over the substrate 304S supporting the epitaxial silicon layer 304. The lower (or back) metal layer 334 is arranged to provide a drain electrode. The metal layers 332, 334 can be electrically connected with external electrodes. FIG. 3W shows the resultant configuration, which is the formed SGT MOSFET in this embodiment.

The operation in FIGS. 3A to 3W can be modified to provide some other embodiments of the disclosure. For example, in some embodiments, starting from the configuration in FIG. 3K, the oxide layer 314 is first isotropically deposited and then isotropically etched back to round the corner defined by the epitaxial silicon layer 304 and the inter poly oxide 310. The oxide layer 312 (can operate as a gate oxide) is then formed (e.g., grown) on the sidewall of the cavity (provided by the epitaxial silicon layer 304) with the rounded corner. For example, in some embodiments, the deposited oxide layer 314 can alternatively be a single or multi-layer dielectric, and the residue 314R may be silicon nitride residue.

Simulation experiments have been performed on the operation 200 of FIG. 2A. The parameters used in the simulation experiments and the results of the simulation experiments are shown in Table 1. In this simulation example, the semiconductor device is a SGT MOSFET as described with reference to FIG. 2B. In this simulation example, the SGT MOSFET has a cell pitch of 2.0 μm, a trench of 4.8 μm deep and 1.28 μm wide. The thickness of the gate oxide (the oxide on the sides of the gate electrode) is 0.06 μm. The thickness of the inter poly oxide (the oxide between the polysilicon body 208 of the shield electrode and the polysilicon body 214 of the gate electrode) is 0.2 μm. In this simulation example, different thicknesses of the deposited oxide (oxide layer 212, which is subsequently isotropically etched to round the corners) are tested. Various measurements are obtained to determine the Q_{g}*Rₛₚ figure of merit (FOM) value and the Q_{gd}*Rₛₚ figure of merit (FOM) value for these different cases. In Table 1, the more negative the value of the improvement ratio, the better the improvement. From Table 1, it can be seen that in this example simulation the best improvement in the Q_{gd}*Rₛₚ figure of merit (FOM) value is obtained when the deposited oxide thickness is 0.3 μm whereas the best improvement in the Q_{g}*Rₛₚ figure of merit (FOM) value is obtained when the deposited oxide thickness is 0.4 μm. It can be seen that improvement in these FOM values can be obtained even when the deposited oxide thickness is 0.05 μm.

TABLE 1
Data and results of simulation experiments performed
on the operation embodiment in one example

| | Deposited oxide thickness (μm) | | | | | | |
|---|---|---|---|---|---|---|---|
| | 0 | 0.05 | 0.1 | 0.2 | 0.3 | 0.4 | 0.5 |
| Gate-source charge Q_{gs} | 5.43 | 5.44 | 5.37 | 5.18 | 4.93 | 4.9 | 4.9 |
| (nC) | | | | | | | |
| Gate-drain charge Q_{gd} | 5.1 | 4.7 | 4.4 | 3.8 | 2.9 | 2.7 | 2.7 |
| (nC) | | | | | | | |
| Gate charge Q_{g} (nC) | 26 | 24.9 | 24.5 | 22.6 | 20.7 | 19.1 | 17.8 |
| Breakdown voltage BV | 89.5 | 89.7 | 89.8 | 90 | 90 | 90.1 | 90.2 |
| (V) | | | | | | | |
| On-state specific | 15.4 | 15.5 | 15.7 | 16.1 | 16.9 | 18.2 | 19.8 |
| resistance Rₛₚ | | | | | | | |
| (mΩmm²) | | | | | | | |
| Q_{gd}*Rₛₚ figure of merit | 78.5 | 72.85 | 69.08 | 61.18 | 49.01 | 49.14 | 53.46 |
| (FOM1) value | | | | | | | |
| (mΩmm²nC) | | | | | | | |
| FOM1 improvement | 0% | −7% | −12% | −22% | −38% | −37% | −32% |
| ratio | | | | | | | |
| Q_{g}*Rₛₚ figure of merit | 2041.00 | 1813.97 | 1692.46 | 1382.67 | 1014.51 | 938.57 | 951.59 |
| (FOM2) value | | | | | | | |
| (mΩmm²nC) | | | | | | | |
| FOM2 improvement | 0% | −11% | −17% | −32% | −50% | −54% | −53% |
| ratio | | | | | | | |

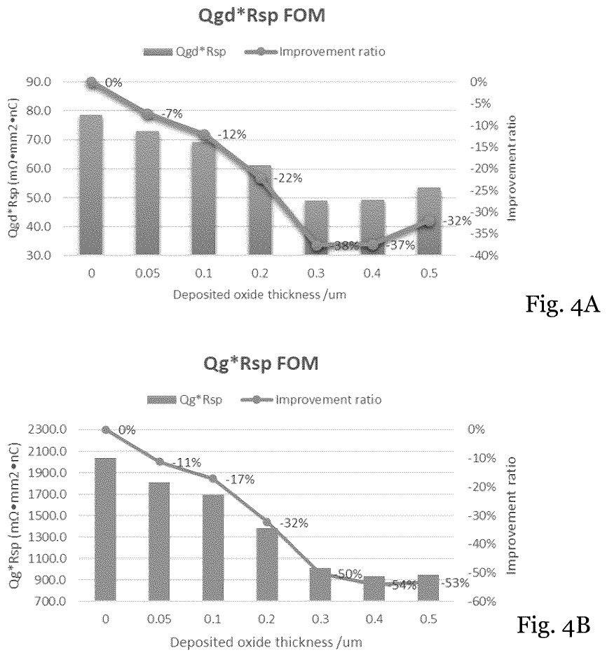

FIGS. 4A and 4B show the respective graphs of the relationship between the Q_{gd}*Rₛₚ (gate-drain charge times on-state specific resistance) figure of merit (FOM) value and the thickness of the deposited oxide and the relationship between the Q_{g}*Rₛₚ (gate charge times on-state specific resistance) figure of merit (FOM) value and the thickness of the deposited oxide, for the operation 200 of FIG. 2A. FIGS. 4A and 4B are graphical representations of the results in Table 1.

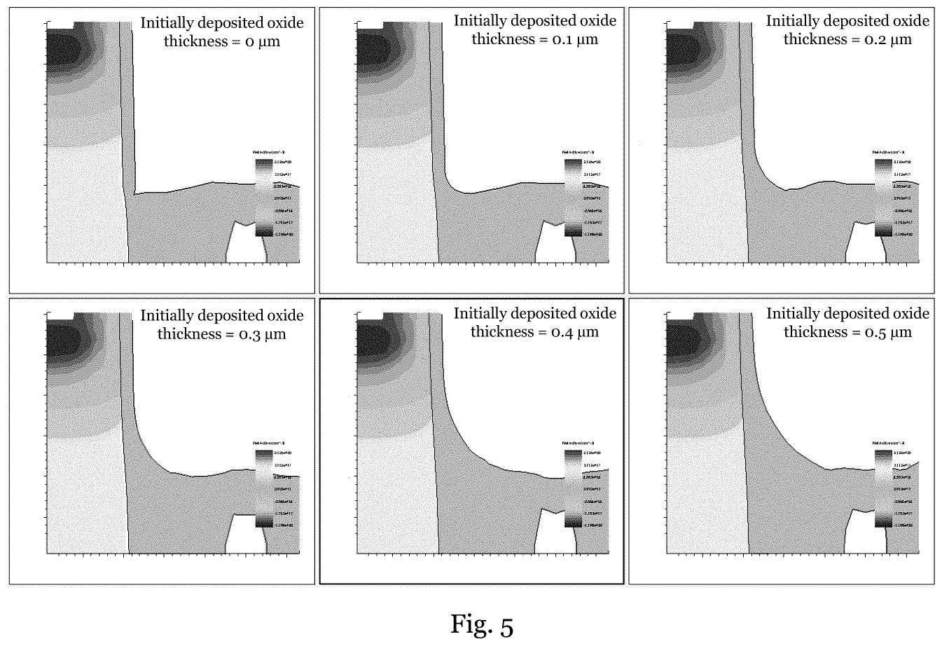

FIG. 5 shows the simulated profiles of the corner for different thicknesses of the 10 deposited oxide layer (oxide layer 212, which is subsequently isotropically etched to round the corners). It can be seen that the application of the deposited oxide (subsequently isotropically etched) can generally assist in rounding the corner. It can be observed that the corner rounding becomes more prominent as a thicker oxide layer is deposited (before being isotropically etched).

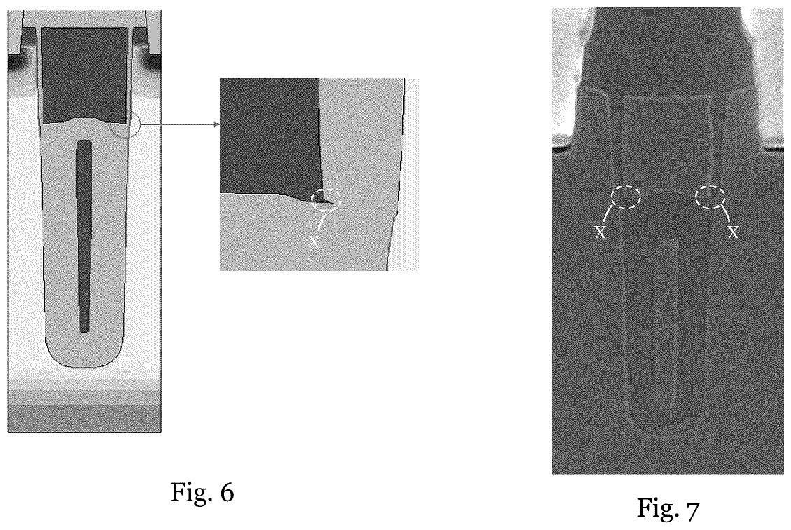

FIG. 6 shows a SGT MOSFET fabricated using the operation 200 without performing stages (v) and (vi) in FIG. 2A (i.e., without depositing and then isotropically etching the oxide to round the corners). The operation 200 without stages (v) and (vi) is not part of this invention. It can be seen that a sharp concave gate corner X is formed at the bottom of the gate. Such concave gate corner X may be formed during thermal growth of gate oxide (from silicon) as a result of material property change from silicon to oxide, and so subsequently when the gate poly is filled in the space defined at least by the gate oxide, the gate poly fills the sharp concave gate corner X.

FIG. 7 shows an SEM image of a SGT MOSFET fabricated using the same method as FIG. 6. Again, sharp concave gate corners X can be seen at the bottom of the gate.

The above embodiments of the disclosure have provided, among other things, a technique for reducing sharpness at least one corner of an electrode in a semiconductor device. The technique can be used, in some embodiments, to reduce sharpness of corner(s) at the bottom of the gate oxide or gate electrode (or the cavity receiving it). This can provide a higher gate oxide breakdown voltage, and can lower gate oxide current leakage. In some embodiments, the gate oxide electric stress can be reduced so the gate region (gate electrode and/or gate oxide) in general becomes more reliable. Some embodiments of the disclosure also provide a semiconductor device with improved FOM values.

It will be appreciated by a person skilled in the art that variations and/or modifications may be made to the described and/or illustrated embodiments of the disclosure to provide other embodiments of the disclosure. The described and/or illustrated embodiments of the disclosure should therefore be considered in all respects as illustrative, not restrictive. Example optional features of some embodiments of the disclosure are provided in the summary and the description. Some embodiments of the disclosure can include one or more of these optional features whereas some embodiments of the disclosure can lack one or more of these optional features.

While the semiconductor device in some of the illustrated and/or described embodiments is SGT MOSFET, it should be appreciated that the method of the disclosure can be used to fabricate other types of semiconductor device. An example of the semiconductor device include trench-gate based semiconductor device such as trench-gate based MOSFET or trench-gate based IGBT, which may or may not have a shielded gate structure.

While the trench-gate based semiconductor device in some of the illustrated and/or described embodiments only show one trench, it should be appreciated that in some embodiments the trench-gate based semiconductor device can include multiple cells with multiple such trenches which are spaced-apart (e.g., one trench in respect of each respective cell). While the semiconductor body (that provides epitaxial layer(s) and optionally the substrate) of the semiconductor device in some of the illustrated and/or described embodiments include a silicon body, in some other embodiments, the semiconductor body can be made of other semiconductor material and may include, for example, a silicon carbon (SiC) body or a gallium nitride (GaN) body.

1. A method for providing an electrode in a semiconductor device, comprising the steps of:
obtaining a semiconductor device comprising a semiconductor body with a first surface and a cavity extending from the first surface, the cavity comprising a corner defined by a sidewall and a base wall;
forming a material layer in the cavity overlying the corner;
isotropically etching the material layer so that the etched material formed over the corner rounds the corner; and
forming an electrode in the cavity with the rounded corner.

2. The method of claim 1, wherein the material layer comprises a dielectric layer, and wherein the etched material formed over the corner comprises etched dielectric.

3. The method of claim 1, wherein forming the material layer further comprises the step of:
forming the material layer on all walls of the cavity so that the material layer covers all of the walls of the cavity.

4. The method of claim 1, wherein forming the material layer further comprises the step of:
depositing the material layer.

5. The method of claim 4, wherein depositing the material layer further comprises the step of:
isotropically depositing the material layer.

6. The method of claim 1, wherein the sidewall and the base wall are dielectric walls.

7. The method of claim 1, wherein the electrode comprises a gate electrode.

8. The method of claim 1, wherein obtaining the semiconductor device further comprises the steps of:
obtaining a body comprising a trench with a first trench portion and a second trench portion, the first trench portion receives a dielectric arrangement with another electrode embedded in the dielectric arrangement; and
wherein the cavity is in the second trench portion.

9. The method of claim 8,
wherein the dielectric arrangement provides the base wall of the cavity; and/or
wherein the another electrode comprises a shield electrode.

10. The method of claim 8,
wherein obtaining the semiconductor device further comprises the step of forming a dielectric layer on a sidewall of the second trench portion so that the formed dielectric layer provides the sidewall of the cavity.

11. The method of claim 10,
wherein the body comprises a silicon body, the silicon body provides the sidewall of the second trench portion; and
wherein forming the dielectric layer on the sidewall comprises thermally oxidizing the sidewall.

12. The method of claim 1, further comprising:
forming a dielectric layer on a sidewall of the cavity with the rounded corner; and
forming the electrode in the cavity with the rounded corner and the dielectric sidewall.

13. The method of claim 1, wherein the semiconductor device is a trench-gate based semiconductor device.

14. The method of claim 13, wherein the trench-gate based semiconductor device is a shielded gate trench (SGT) semiconductor device.

15. The method of claim 1, wherein the semiconductor device is a trench-gate based metal oxide semiconductor field effect transistor (MOSFET).

16. The method of claim 1, wherein the semiconductor device is a trench-gate based insulated gate bipolar transistor (IGBT).

17. The method of claim 13, wherein the trench-gate based semiconductor device is a SGT MOSFET.

18. The method of claim 13, wherein the trench-gate based semiconductor device is a SGT IGBT.

19. A semiconductor device formed using the method of claim 1.
